(19) United States
(12) Patent Application Publication
(10) Pub. No.: US 2018/0047697 A1
(43) Pub. Date: Feb. 15, 2018

(54) CHIP ARRANGEMENT AND METHOD FOR FORMING A CONTACT CONNECTION

(71) Applicant: PAC TECH - PACKAGING TECHNOLOGIES GMBH, Nauen (DE)

(72) Inventors: Heinrich Lüdeke, Mettmann (DE); Ricardo Geelhaar, Berlin (DE)

(21) Appl. No.: 15/557,591

(22) PCT Filed: Feb. 15, 2016
(86) PCT No.: PCT/EP2016/053169

§ 371 Date: Sep. 12, 2017

(30) Foreign Application Priority Data
Mar. 16, 2015 (DE) 10 2015 103 779.3

(51) Int. Cl. H01L 23/00

(52) U.S. Cl. CPC H01L 24/48; H01L 24/85; H01L 24/03; H01L 24/05; H01L 2224/48839; H01L 2224/48847; H01L 2224/85051; H01L 2224/8584; H01L 2224/85203; H01L 2924/13091; H01L 2224/45147; H01L 2224/45005; H01L 2224/48091; H01L 2224/48106; H01L 2924/13055; H01L 2224/48227; H01L 2224/48247; H01L 2224/85379; H01L 2224/04042; H01L 2224/05147; H01L 2224/05139; H01L 2224/05155; H01L 2224/05144; H01L 2224/05124; H01L 2224/05164; H01L 2224/85214

(57) ABSTRACT

The invention relates to a chip arrangement (10) and to a method for forming a contact connection (11) between a chip (18), in particular a power transistor or the like, and a conductor material track (14), the conductor material track being formed on a non-conductive substrate (12), the chip being arranged on the substrate or on a conductor material track (15), a silver paste (29) or a copper paste being applied to each of a chip contact surface (25) of the chip and the conductor material track (28), a contact conductor (30) being immersed into the silver paste or the copper paste on the chip contact surface and into the silver paste or the copper paste on the conductor material track, a solvent contained in the silver paste or the copper paste being at least partially vaporized by heating and the contact connection being formed by sintering the silver paste or the copper paste by means of laser energy.

The invention relates to a chip arrangement and to a method for forming a contact connection between a chip, in particular a power transistor or the like, and a conductor material track, the conductor material track being formed on a non-conductive substrate and the chip being arranged on the substrate or on a conductor material track.

The chips known from the state of the art can be realized with a housing and also as a naked semiconductor component. These chips are regularly called die, bare die or bare chip. Chips of this kind are processed without a housing and are applied directly to a substrate or to a printed circuit board. In doing so, a direct contact can be formed between the chip contact surfaces of the chip and conductor material tracks. Other chip contact surfaces of the chip can be connected to other conductor material tracks via contact conductors or so-called bond wires. Contact connections of this kind are also regularly formed on power transistors. In that context, for example, a lower chip contact surface of a power transistor or chip is arranged on a conductor material track and connected to it substantially across its entire surface. An upper chip contact surface of the chip opposite of the contacted lower chip contact surface is connected to another conductor material track running next to the chip via a plurality of bond wires by ultrasonic bonding or soldering, for example. This chip arrangement ensures the availability of a sufficiently large conductor cross-section for the transmission of high currents. Also, comparatively thick bond wires made of aluminum can be used for applications of this kind.

In particular in case of power transistors, such as MOSFETs, IGBTs and diodes for power modules, high thermal and electrical stresses occur, for example in a power range of 15 to 150 kW. These stresses can easily lead to component failure of the contact connection and of the chip arrangement. Moreover, the use of the chip arrangement in vehicles or wind energy plants, for example, may further reduce a service life of the chip arrangement because of high temperature fluctuations. For instance, a contact connection may break or be disconnected because of these stresses. Furthermore, a solder connection between a contact conductor and a conductor material track or a chip contact surface can only be heated to a maximum of 175° C. without permanently damaging the contact connection. Furthermore, a chip arrangement of this kind is comparatively expensive to produce because a plurality of contact conductors has to be arranged between the chip contact surface and the conductor material track in order to transmit high currents.

Therefore, it is the object of the present invention to propose a chip arrangement having a contact connection and a method for forming a contact connection in which the contact connection exhibits improved durability while its production is simplified.

This object is attained by a method for forming a contact connection having the features of claim 1 and by a chip arrangement having the features of claim 14.

In the method according to the invention for forming a contact connection between a chip, in particular a power transistor or the like, and a conductor material track, the conductor material track is formed on a non-conductive substrate, the chip being arranged on the substrate or on a conductor material track, a silver paste or a copper paste being applied to each of a chip contact surface of the chip and the conductor material track, a contact conductor being immersed into the silver paste or the copper paste on the chip contact surface and into the silver paste or the copper paste on the conductor material track, a solvent contained in the silver paste or the copper paste being at least partially vaporized by heating and the contact connection being formed by sintering the silver paste or the copper paste by means of laser energy.

The substrate can be made of a plastic material or a ceramic material, conductor material tracks for connecting electronic components or semiconductor components being formed on the substrate at first. This may take place by way of a method well understood in the state of the art. The chip is subsequently arranged directly on the non-conductive substrate or on a conductor material track. If the chip is arranged on the conductor material track, it is electrically connected to the latter. On an upper side of the chip facing away from the substrate or the conductor material track, at least one upper chip contact surface is formed for forming a contact with the chip. By forming the contact connection, the chip contact surface will now be connected to a conductor material track adjacent relative to the chip or to another conductor material track via a contact conductor. To this end, a liquid or pasty silver paste or copper paste is applied to the conductor material track adjacent relative to the chip. The paste or metal paste is also applied to the upper chip contact surface. The paste can be applied automatically by means of an applicator. Then, the contact conductor is immersed into the paste on the chip contact surface and into the paste on the conductor material track so that the contact conductor is at least partially surrounded by the paste in each case. The silver paste or copper paste contains a solvent, which is at least partially vaporized by heating, which may lead to a reduction of the volume of the applied paste. Depending on the extent of heating, the solvent can be vaporized by evaporation or boiling. The ultimate formation of the contact connection takes place by sintering of the silver paste or copper paste by means of laser energy or laser sintering, a laser beam being aimed directly or indirectly at an area of the contact connection. Silver powder or silver particles contained in the silver paste will at least partially melt or sinter together, thus forming an electrical connection between the contact conductor and the chip contact surface and between the contact conductor and the conductor material track. The copper paste is sintered in the same way. An application of the silver paste or the copper paste to the chip contact surface, the conductor material track and, if applicable, the contact conductor and the subsequent sintering can take place in parallel or in sequence, wherein it is immaterial then whether the chip contact surface or the conductor material track is the first to be provided with paste or sintered. It is also possible to first finish forming a contact on the chip contact surface or on the conductor material track and to subsequently apply and sinter the paste for forming the second contact. Regarding the order of the method steps, the contact conductor can also first be arranged on the chip contact surface or the conductor material track before the paste is applied. Then, the paste is applied to the chip contact surface or the conductor material track with the contact conductor in such a manner that the contact conductor is simultaneously immersed in the paste.

Owing to the fact that a silver paste or a copper paste is used instead of a solder to produce the contact connection, the contact connection lasts substantially longer. The sintered paste is substantially more resistant to high temperature fluctuations and high operating temperatures. For instance, operating temperatures of the chip of up to 300° C. can be achieved with sintered silver paste. Moreover, it is no longer necessary to form a large number of contact connections between the chip terminal surface and the conductor material track in order to be able to transmit high currents. The method according to the invention is largely independent from a cross-section of the contact conductor, making it possible to substantially reduce the number of contact conductors and contact connections, which makes the production of the chip arrangement more cost-effective on the whole.

A stranded wire, preferably a flat litz wire, particularly preferably a stranded wire or a flat litz wire made of copper or a copper alloy can be used as a contact conductor. A stranded wire is particularly flexible, which means that in contrast to a contact conductor in the form of a solid wire, no shear or tensile stresses such as those potentially caused by large temperature differences can occur in the respective contacts on the chip contact surface or the conductor material track. As opposed to a wire or bond wire, a flat litz wire has a relatively large cross-section, which is why it is able to transmit high currents.

Also, the stranded wire can be at least partially infiltrated by the silver paste or copper paste. By immersing the stranded wire into the paste, the paste, that is silver particles or copper particles, can penetrate the stranded wire so that a particularly tight connection between the silver particles or copper particles and the stranded wire can be formed during sintering. The paste can also be absorbed by the stranded wire owing to its capillary effect so that the stranded wire is filled with silver particles or copper particles in the area of the chip contact surface and of the conductor material track.

Furthermore, it may be envisaged that only one stranded wire is used per chip contact surface. This is made possible by the fact that the stranded wire or the flat litz wire can have a comparatively large width that is approximated to the dimensions of the chip contact surface. In this case, it will no longer be necessary to use a plurality of contact conductors. If only one stranded wire is used to connect the chip contact surface and the conductor material track, the method can be implemented in a particularly quick and thus cost-effective manner.

Heating of the silver paste or the copper paste can be achieved by arranging the substrate on or on top of a heating element. The substrate and thus the conductor material track as well as the chip contact surface can then be heated until the solvent of the paste vaporizes. Thus, the use of an oven or of a similar device for external heating of the paste can be entirely omitted.

Moreover, it may be envisaged that the substrate is supported by means of a clamping means during heating. On the one hand, the substrate can thus be exactly positioned, and on the other hand, the clamping means can have a heating element or form the heating element itself. In this way, heating of the silver paste or the copper paste to vaporize the solvent is simplified even further.

In the course of the method, the silver paste or the copper paste can be sintered prior to a complete vaporization of the solvent. Thus, the silver paste or copper paste can be prevented from fully drying before it is sintered. Completely solvent-free or dried paste is prone to fractures due to the drying process or due to movement, which may be conducive to failure of the contact connection.

The contact conductor can be pressed onto the chip contact surface and/or onto the conductor material surface by means of a pressing device during sintering. In this way, a particularly tight contact between the contact conductor and the chip contact surface or the conductor material track can be formed. Furthermore, a formation of undesired cracks during cooling of the sintered silver paste or copper paste can be avoided.

In another embodiment of the method, the contact conductor can be severed after sintering. For example, the contact conductor can be stored on a coil or reel and can be fed to the chip contact surface and to the conductor material track in an automated manner. In doing so, first an end of the contact conductor can be placed on the chip contact surface. A section of the contact conductor can be arranged on the conductor material track or vice-versa. After sintering of the silver paste or the copper paste and formation of the contact connection, the contact conductor can be severed or cut at the section so that a free end of the contact conductor is available again for forming another contact connection.

The chip contact surface can be formed by applying a copper strip to a chip surface. In that case, the chip surface can be made of a semiconductor material, such as silicon. By applying the copper strip, metallization of the chip surface is particularly simple. The copper strip can also facilitate a formation of the electrical contact with the contact conductor.

Moreover, a contact metallization can be applied to the conductor material track and/or to the chip contact surface. The contact metallization can be comparatively thin and substantially improve wettability of the chip contact surface and of the conductor material track with silver paste or copper paste or molten silver paste or copper paste.

The contact metallization can be formed by physical vapor deposition (PVD), sputter deposition, galvanization or electroless plating.

The contact metallization can be made of silver, nickel, copper, gold, palladium, aluminum or another alloy of one of said metals. A contact metallization made of silver, for example, can be formed to be comparatively thin and also allows a comparatively better current density distribution and a particularly favorable thermal dissipation of heat energy, such as for cooling the chip. Moreover, the silver paste or the copper paste can merge particularly well with the silver of the contact metallization during sintering.

The chip arrangement according to the invention, in particular for power transistors or the like, comprises a chip, a non-conductive substrate having a conductor material track formed thereon and a contact conductor, the chip being arranged on the substrate or on a conductor material track, wherein a silver paste or a copper paste is applied to each of a chip contact surface of the chip and the conductor material track, the contact conductor being immersed into the silver paste or the copper paste on the chip contact surface and into the silver paste or the copper paste on the material conductor track, a solvent contained in the silver paste or the copper paste being vaporized by heating and a contact connection being formed by sintering of the silver paste or the copper paste by means of laser energy.

Regarding the advantageous effects of the chip arrangement according to the invention, reference is made to the description of advantages of the method according to the invention. Other advantageous embodiments of the chip arrangement become apparent from the dependent claims back-referenced to claim 1.

In the following description, preferred embodiments of the invention will be explained in more detail with reference to the accompanying drawing.

In the drawing:

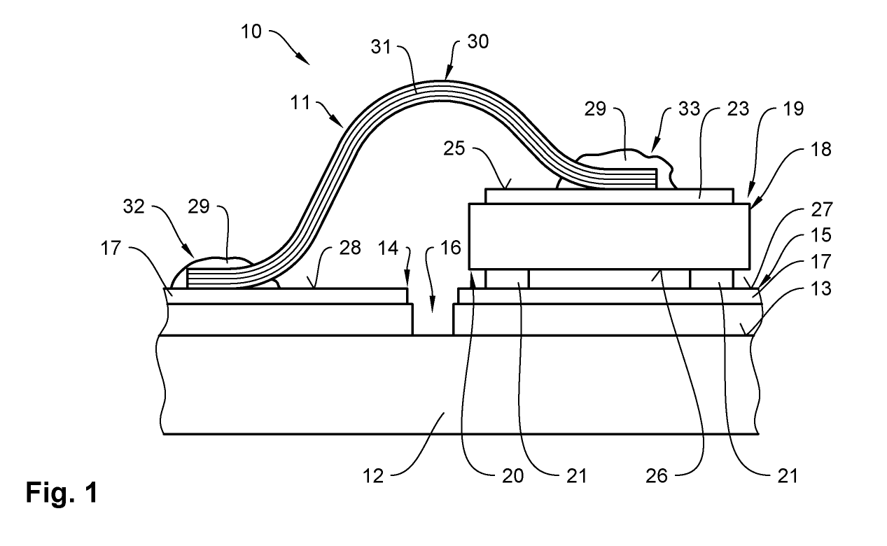

FIG. 1 shows a schematic sectional view of a first embodiment of a chip arrangement during a method step;

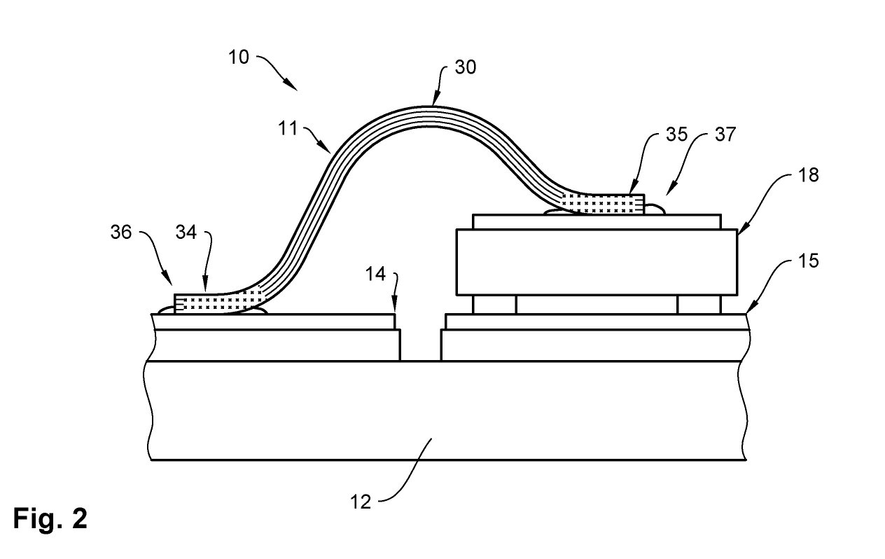

FIG. 2 shows a schematic sectional view of the chip arrangement of FIG. 1 after completion of a contact connection;

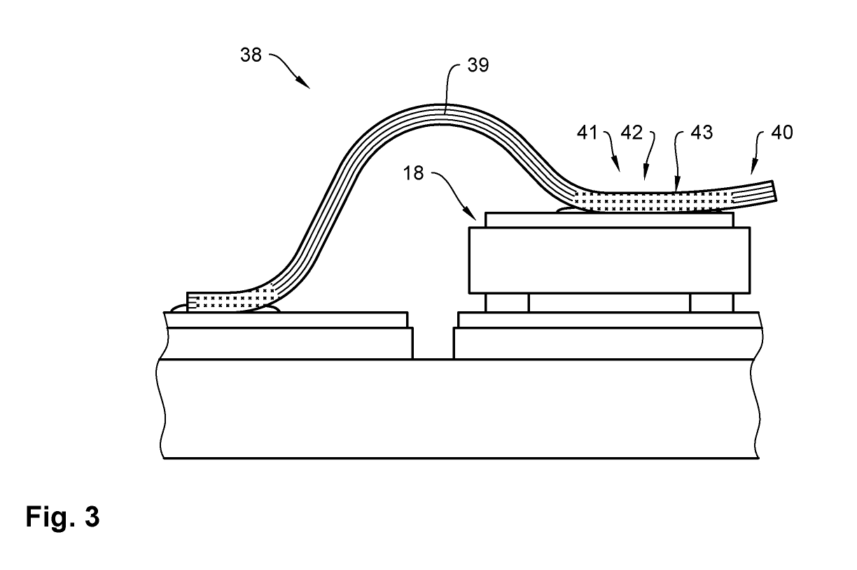

FIG. 3 shows a schematic sectional view of a second embodiment of a chip arrangement; and

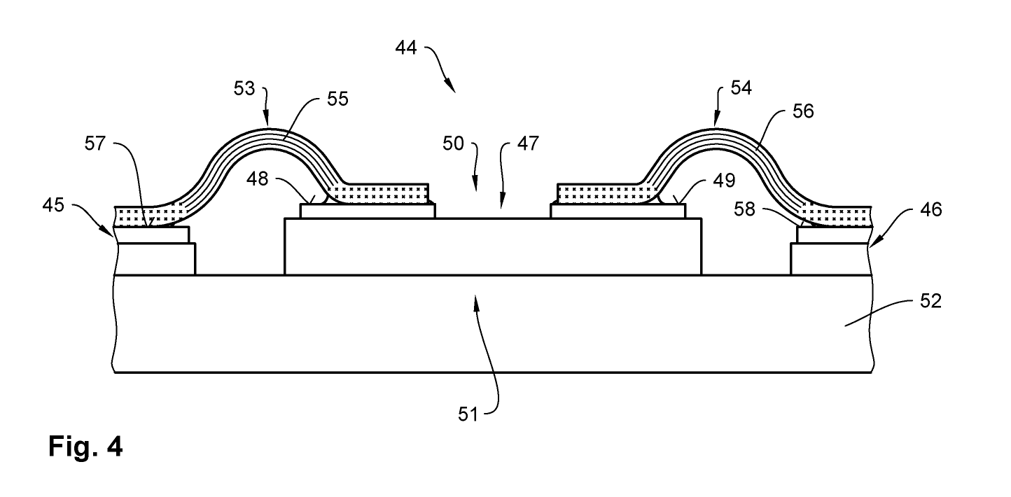

FIG. 4 shows a schematic sectional view of a third embodiment of a chip arrangement.

FIG. 1 shows a chip arrangement 10 in a schematic sectional view during the production of a contact connection 11. The chip arrangement 10 comprises a non-conductive substrate 12, on whose surface 13 a plurality of different conductor material tracks 14 and 15 are formed. The conductor material tracks 14 and 15 are separated from each other via an isolating gap 16 and are thus electrically isolated from each other. A contact metallization 17 made of silver or a silver alloy is formed on or applied to each of the conductor material tracks 14 and 15. Alternatively, the contact metallization 17 can also be made of nickel, copper, gold, palladium, aluminum or another alloy of one of said metals. A chip 18, which is made of a semiconductor material, is formed on conductor material track 15. A contact metallization 23 made of silver or a silver alloy is applied to a rear side 19 of the chip 18 facing away from conductor material track 15, and contact bumps 21 are applied to a front side 20 of the chip 18 facing toward conductor material track 15. The contact bumps 21 connect the chip 18 to the conductor material track 15. Accordingly, a rear chip contact surface 25 and a front chip contact surface 26 are formed on the chip 18. The chip contact surface 26 of the chip 18 is contacted, that is electrically connected, with a conductor surface 27 of conductor material track 15. A defined amount of silver paste 29 has been applied to each of a conductor surface 28 of conductor material track 14 and to the chip contact surface 25 of the chip 18. A contact conductor 30 is realized as a flat litz wire 31 made of copper and is immersed into the silver paste 29 with each of its ends 32 and 33, the silver paste 29 substantially surrounding the ends 32 and 33.

As can be taken from FIG. 2, the silver paste 29 was sintered after the solvent contained therein had largely vaporized. Sintering took place in that laser energy was introduced to the silver paste 29 and each of the ends 32 and 33. In this way, a first contact 34 of the contact connection 11 was formed with the silver paste 29 and the end 32 on the conductor surface 28 and a second contact 35 of the contact connection 11 was formed with the silver paste 29 and the end 33 on the chip contact surface 25. The silver particles (not visible) of the silver paste 29 penetrated the ends 32 and 33 and were sintered or partially melted together by the sintering, a particularly tight connection having been formed with the filaments (not visible) of the flat litz wire 31 and the conductor surface 28 and the chip contact surface 25, respectively. Thus, the sintered silver paste 29 is solidified in contact areas 36 and 37.

FIG. 3 shows a second embodiment of a chip arrangement 38, which differs from the chip arrangement shown in FIG. 2 in that it comprises a flat litz wire 39 that was severed only after sintering of the silver paste 29. An end 40 of the flat litz wire 39 thus protrudes from a contact area 41, a section 42 of the flat litz wire 39 serving to form a contact 43 with the chip 18.

FIG. 4 shows a third embodiment of a chip arrangement 44, which differs from the chip arrangement shown in FIG. 2 in that it comprises conductor material tracks 45 and 46, between which the chip 47 is arranged. The chip 47 forms two front chip contact surfaces 48 and 49 on a front side 50 of the chip 47, a rear side 51 of the chip 47 being arranged directly on a substrate 52. Each of the chip contact surfaces 48 and 49 is connected to conductor surfaces 57 and 58 of conductor material tracks 45 and 46, respectively, via contact conductors 53 and 54, which are realized as flat litz wires 55 and 56, respectively.

In the embodiment examples described above, the silver paste can also be replaced with copper paste.

1. A method for forming a contact connection between a chip and a conductor material track, the conductor material track being formed on a non-conductive substrate, the chip being arranged on the substrate or on another conductor material track,
comprising the steps of
applying a silver paste or a copper paste to each of a chip contact surface of the chip and the conductor material track, immersing a contact conductor into the silver paste or the copper paste on the chip contact surface and into the silver paste or the copper paste on the conductor material track, heating the silver paste or the copper paste to at least partially vaporize a solvent contained in the silver paste or the copper paste and forming the contact connection by sintering the silver paste or the copper paste with laser energy.

2. The method according to claim 1,
wherein
a stranded wire is used as a contact conductor.

3. The method according to claim 2,
wherein
the stranded wire is at least partially infiltrated by the silver paste or the copper paste.

4. The method according to claim 2,
wherein
only one stranded wire is used per chip contact surface.

5. The method according to claim 1,
wherein
the step of heating of the silver paste or the copper paste is achieved by arranging the substrate on or on top of a heating element.

6. The method according to claim 1,
further comprising the step of supporting the substrate with a clamp during heating.

7. The method according to claim 1,
further comprising the step of sintering the silver paste or the copper paste prior to complete vaporization of the solvent.

8. The method according to claim 1,
further comprising the step of pressing the contact conductor onto the chip contact surface and/or onto the conductor material track during sintering.

9. The method according to claim 1,
further comprising the step of severing the contact conductor after sintering.

10. The method according to claim 1,
wherein
the chip contact surface is formed by applying a copper strip to a chip surface.

11. The method according to claim 1,
wherein
a contact metallization is applied to the conductor material track and/or to the chip contact surface.

12. The method according to claim 11,
wherein
the contact metallization is formed by physical vapor deposition (PVD), sputter deposition, galvanization or electroless plating.

13. The method according to claim 11,
wherein
the contact metallization is made of silver, nickel, copper, gold, palladium, aluminum or an alloy of one of said metals.

14. A chip arrangement comprising a chip, a non-conductive substrate having a conductor material track formed thereon and a contact conductor, the chip being arranged on the substrate or on a conductor material track,
wherein
a silver paste or a copper paste is applied to each of a chip contact surface of the chip and the conductor material track, the contact conductor being immersed into the silver paste or the copper paste on the chip contact surface and into the silver paste or the copper paste on the conductor material track, a solvent contained in the silver paste or the copper paste being vaporized by heating and a contact connection being formed by sintering of the silver paste or the copper paste with laser energy.

15. The method of claim 1, wherein the chip is a power transistor.

16. The method of claim 2, wherein the stranded wire is a flat litz wire made of copper or a copper alloy.

17. The chip arrangement of claim 14, wherein the chip comprises a power transistor.
